(19) United States
(12) Patent Application Publication
(10) Pub. No.: US 2026/0068196 A1
(43) Pub. Date: Mar. 5, 2026

(54) SEMICONDUCTOR MEMORY DEVICE

(71) Applicant: Samsung Electronics Co., Ltd., Suwon-si (KR)

(72) Inventors: Eui-Hyuk Kim, Suwon-si (KR); Seung Chan Kee, Suwon-si (KR); Min Kyeong Seo, Suwon-si (KR); Ji Yeon Chang, Suwon-si (KR); Mi-Kyung Park, Suwon-si (KR); Jong-Min Lee, Suwon-si (KR)

(21) Appl. No.: 19/215,433

(22) Filed: May 22, 2025

(30) Foreign Application Priority Data
Sep. 5, 2024 (KR) 10-2024-0120527

(51) Int. Cl. H10D 1/68; H10B 12/00

(52) U.S. Cl. CPC H10D 1/696; H10B 12/315; H10B 12/482; H10B 12/485; H10B 12/488; H10D 1/716; H10B 12/033

(57) ABSTRACT

A semiconductor memory device comprises a storage pad on a substrate, a lower electrode structure on the storage pad, an upper support pattern on the lower electrode structure opposite the storage pad, a capacitor dielectric film on the lower electrode structure and the upper support pattern, and an upper electrode on the capacitor dielectric film, wherein the lower electrode structure includes a first lower electrode, a second lower electrode, and a third lower electrode, the second lower electrode is between the first lower electrode and the third lower electrode, and the third lower electrode extends on an upper face of the first lower electrode and an upper face of the second lower electrode that are opposite the storage pad.

### CROSS-REFERENCE TO RELATED APPLICATION

This application claims priority from Korean Patent Application No. 10-2024-0120527 filed on Sep. 5, 2024, in the Korean Intellectual Property Office, and all the benefits accruing therefrom under 35 U.S.C. 119, the contents of which in its entirety are herein incorporated by reference.

### TECHNICAL FIELD

The present disclosure relates to a semiconductor memory device.

### BACKGROUND

As semiconductor elements have become higher capacity and more highly integrated, design rules have also been continually decreasing. Such a trend also appears in a DRAM, which is one type of memory semiconductor element. In order for a DRAM device to operate, capacitance (electrostatic capacity) of a certain level or more may be required for each cell.

In order to increase the capacitance, a method of increasing an aspect ratio of a lower electrode of a capacitor or a method of increasing a contact area between the lower electrode of the capacitor and a dielectric film has been researched. When increasing the aspect ratio of the lower electrode of the capacitor, a supporter that may support the lower electrode of the capacitor is typically used to prevent the lower electrode of the capacitor from tilting or bending.

### SUMMARY

Aspects of the present disclosure provide a semiconductor memory device having improved performance and reliability.

According to an aspect of the present disclosure, there is provided a semiconductor memory device comprising a storage pad on a substrate, a lower electrode structure on the storage pad. an upper support pattern on the lower electrode structure opposite the storage pad, a capacitor dielectric film on the lower electrode structure and the upper support pattern, and an upper electrode on the capacitor dielectric film, wherein the lower electrode structure includes a first lower electrode, a second lower electrode, and a third lower electrode, wherein the second lower electrode is between the first lower electrode and the third lower electrode, and wherein the third lower electrode extends on an upper face of the first lower electrode and an upper face of the second lower electrode that are opposite the storage pad.

According to an aspect of the present disclosure, there is provided a semiconductor memory device comprising a storage pad on a substrate, a lower electrode structure on the storage pad, an upper support pattern on the lower electrode structure opposite the storage pad, a capacitor dielectric film on the lower electrode structure and the upper support pattern, and an upper electrode on the capacitor dielectric film, wherein the lower electrode structure includes a first lower electrode, a second lower electrode, and a third lower electrode, wherein the first lower electrode has an outer wall that is in contact with the capacitor dielectric film, and an inner wall that is opposite the outer wall, wherein the second lower electrode extends conformally along the inner wall of the first lower electrode, and the third lower electrode extends on an upper face of the first lower electrode and an upper face of the second lower electrode that are opposite the storage pad.

According to an aspect of the present disclosure, there is provided a semiconductor memory device comprising a substrate that includes an active region between portions of an element isolation film and extending in a first direction, the active region including a first portion and a second portion on opposing sides of the first portion, a word line that extends in a second direction different from the first direction in the substrate and the element isolation film, and crosses between the first portion of the active region and the second portion of the active region, a bit line contact that is connected to the first portion of the active region, a bit line that is on and is connected to the bit line contact and extends in a third direction that is different from the first and second directions, a storage pad that is connected to the second portion of the active region, a lower electrode structure that is on the storage pad, an upper support pattern that is on the lower electrode structure opposite the storage pad, a capacitor dielectric film that is on the lower electrode structure and the upper support pattern, and an upper electrode that is on the capacitor dielectric film, wherein the lower electrode structure includes a first lower electrode, a second lower electrode, and a third lower electrode, wherein the second lower electrode is between the first lower electrode and the third lower electrode, and wherein the third lower electrode extends on an upper face of the first lower electrode and an upper face of the second lower electrode that are opposite the storage pad.

However, aspects of the present disclosure are not restricted to those set forth herein. The above and other aspects of the present disclosure will become more apparent to one of ordinary skill in the art to which the present disclosure pertains by referencing the following detailed description.

### BRIEF DESCRIPTION OF DRAWINGS

The above and other aspects and features of the present disclosure will become more apparent by describing in detail illustrative embodiments thereof with reference to the attached drawings, in which:

FIG. 1 is a plan view for explaining a semiconductor memory device according to some embodiments.

FIG. 2 is an example cross-sectional view taken along I-I of FIG. 1.

FIG. 3 is an example cross-sectional view taken along I-I of FIG. 1 according to some embodiments of the present disclosure.

FIG. 4 is an example cross-sectional view taken along I-I of FIG. 1 according to some embodiments of the present disclosure.

FIG. 5 is an example cross-sectional view taken along I-I of FIG. 1 according to some embodiments of the present disclosure.

FIG. 6 is an example cross-sectional view taken along I-I of FIG. 1 according to some embodiments of the present disclosure.

FIGS. 7, 8, 9, 10, 11, 12, 13, 14, 15, 16, and 17 are intermediate stage diagrams for explaining a method for fabricating a semiconductor memory device according to some embodiments.

FIGS. 18, 19, and 20 are diagrams for explaining a semiconductor memory device according to some embodiments.

FIG. 21 is a layout diagram for explaining a semiconductor memory device according to some embodiments.

FIG. 22 is a perspective view for explaining the semiconductor memory device according to some embodiments.

FIG. 23 is a cross-sectional view taken along C-C and D-D of FIG. 21.

FIG. 24 is a layout diagram for explaining a semiconductor memory device according to some embodiments.

FIG. 25 is a perspective view for explaining a semiconductor memory device according to some embodiments.

### DETAILED DESCRIPTION OF EMBODIMENTS

Although terms such as first and second are used to describe various elements or components in the present specification, these elements or components are not limited by these terms. These terms are only used to distinguish a single element or component from other elements or components. Therefore, a first element or component referred to below may be a second element or component within the technical idea of the present disclosure. The terms “comprises,” “comprising,” “includes” and/or “including,” when used herein, specify the presence of stated elements, but do not preclude the presence of additional elements. The term “and/or” includes any and all combinations of one or more of the associated listed items. The term “connected” may be used herein to refer to a physical and/or electrical connection. When components or layers are referred to herein as “directly” on, or “in direct contact” or “directly connected,” no intervening components or layers are present. Likewise, when components are “immediately” adjacent to one another, no intervening components may be present.

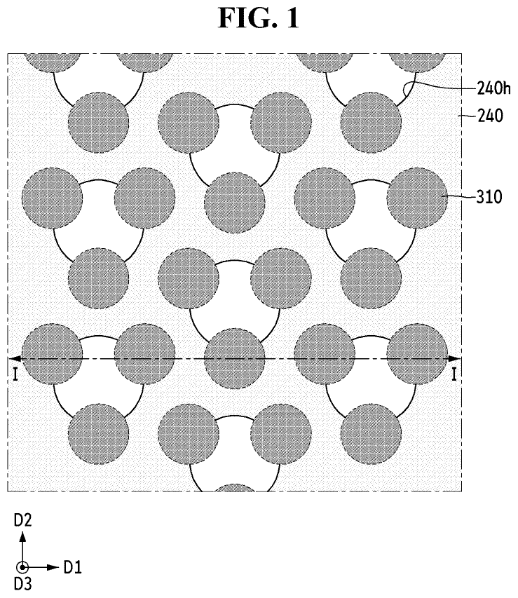

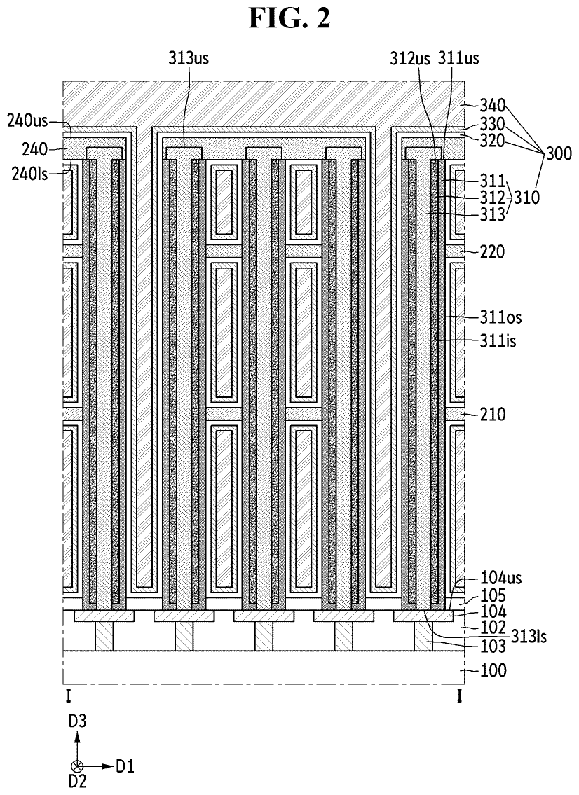

FIG. 1 is a plan view for explaining a semiconductor memory device according to some embodiments. FIG. 2 is an example cross-sectional view taken along I-I of FIG. 1.

Referring to FIGS. 1 and 2, a semiconductor memory device according to some embodiments may include a substrate 100, a storage pad 104, and a capacitor structure 300.

The substrate 100 may be bulk silicon or silicon-on-insulator (SOI). In contrast, the substrate 100 may be a silicon substrate, or may include other materials, for example, but not limited to, silicon germanium, silicon germanium on insulator (SGOI), indium antimonide, lead telluride, indium arsenide, indium phosphide, gallium arsenide or gallium antimonide. In the following description, the substrate 100 will be described as a silicon substrate.

The interlayer insulating film 102 may be disposed on the substrate 100. For example, the interlayer insulating film 102 may include at least one of silicon oxide, silicon nitride, silicon oxynitride film (SiON), silicon oxycarbonitride film (SiOCN), and combinations thereof. The interlayer insulating film 102 may be a single layer or a multi-layer.

The storage contact 103 and the storage pad 104 may be disposed on the substrate 100. The storage contact 103 and the storage pad 104 may be disposed inside the interlayer insulating film 102. The storage pad 104 may be disposed on the storage contact 103. The storage pad 104 may be connected to the substrate 100 via the storage contact 103. The storage pad 104 may be electrically connected to a conductive region formed on or in the substrate 100.

An etching stop film 105 may be disposed on the interlayer insulating film 102. The etching stop film 105 may expose at least a part of an upper face of the storage pad 104.

The etching stop film 105 may include, for example, at least one of silicon nitride (SiN), silicon carbonitride (SiCN), silicon boron nitride (SiBN), silicon carbonate (SiCO), silicon oxynitride (SiON), silicon oxide (SiO), and silicon oxycarbonitride (SiOCN). For example, silicon carbonate (SiCO) includes silicon (Si), carbon (C) and oxygen (O), but does not mean a ratio between silicon (Si), carbon (C) and oxygen (O).

The capacitor structure 300 may be disposed on the storage pad 104. The capacitor structure 300 may include a lower electrode structure 310, a capacitor dielectric film 320, an upper electrode 330, and an upper plate electrode 340.

The lower electrode structure 310 may be disposed on the storage pad 104. The lower electrode structure 310 penetrates the etching stop film 105, and may be electrically connected to the storage pad 104.

The lower electrode structure 310 may be disposed as or arranged in a honeycomb structure, that is, at the center and each vertex of a hexagon. The lower electrode structures 310 may be disposed at regular intervals. The lower electrode structures 310 may be repeatedly aligned along a first direction D1 and a second direction D2.

Hereinafter, the first direction D1 and the second direction D2 are directions aligned with (e.g., parallel to) the upper face of the substrate 100. The second direction D2 is a direction perpendicular to the first direction D1. The third direction D3 is a direction perpendicular to the upper face of the substrate 100. The upper face, a lower face, an upper part, and a lower part are defined on the basis of the third direction D3.

The lower electrode structure 310 may extend long or may be vertically elongated in the third direction D3. The lower electrode structure 310 may include a first lower electrode 311, a second lower electrode 312, and a third lower electrode 313, which are sequentially stacked, e.g., in a concentric arrangement. In other words, the second lower electrode 312 may be disposed between the first lower electrode 311 and the third lower electrode 313.

The first lower electrode 311 may include an outer wall 311os and an inner wall 311is. The outer wall 311os of the first lower electrode 311 may be in contact with a capacitor dielectric film 320 to be described below. The inner wall 311is of the first lower electrode 311 may be disposed to be opposite to the outer wall 311os. The inner wall 311is of the first lower electrode 311 may be in contact with the second lower electrode 312.

The second lower electrode 312 may be disposed on the first lower electrode 311. The second lower electrode 312 may extend along a profile of the inner wall 311is of the first lower electrode 311. For example, the entire second lower electrode 312 may extend along the profile of the inner wall 311is of the first lower electrode 311, but embodiments of the present disclosure are not limited thereto. As another example, only a part or portion of the second lower electrode 312 may extend along the profile of the inner wall 311is of the first lower electrode 311.

Hereinafter, a lower face 313ls of the third lower electrode 313 refers to the lowermost surface of the third lower electrode 313, which is adjacent the storage pad 104. Spatially relative terms such as “above,” “upper,” “upper portion,” “uppermost surface,” “below,” “lower,” “lower portion,” “lowermost surface,” “side surface,” and the like may be denoted by reference numerals and refer to the drawings with respect to a reference element or surface (such as the substrate 100), except where otherwise indicated. It will be understood that such spatially relative terms are intended to encompass different orientations of the device in use or operation in addition to the orientation depicted in the figures. The lower face 313ls of the third lower electrode 313 may come into direct contact with the upper face 104us of the storage pad 104. The lower face 313ls of the third lower electrode 313 may not come into direct contact with the first lower electrode 311 and/or the second lower electrode 312. The third lower electrode 313 comes into direct contact with the storage pad 104, and may be electrically connected to the storage pad 104.

Hereinafter, an upper face 311us of the first lower electrode 311 refers to the uppermost face of the first lower electrode 311, which is opposite the storage pad 104. The third lower electrode 313 may be disposed on the upper face 311us of the first lower electrode 311. For example, the third lower electrode 313 may cover at least a part of the upper face 311us of the first lower electrode 311.

Hereinafter, an upper face 312us of the second lower electrode 312 refers to the uppermost face of the second lower electrode 312, which is opposite the storage pad 104. The third lower electrode 313 may be disposed on the upper face 312us of the second lower electrode 312. For example, the third lower electrode 313 may cover the entire upper face 312us of the second lower electrode 312.

The first lower electrode 311 includes a material different from the second lower electrode 312 and the third lower electrode 313. The second lower electrode 312 includes a material different from the third lower electrode 313. The first lower electrode 311 may include, for example, titanium nitride (TiN), but embodiments of the present disclosure are not limited thereto. As another example, the first lower electrode 311 may include titanium nitride, tantalum nitride or tungsten nitride.

The second lower electrode 312 may include, for example, niobium nitride (NbN), but the embodiments of the present disclosure are not limited thereto. As another example, the second lower electrode 312 may include titanium nitride, tantalum nitride or tungsten nitride.

The third lower electrode 313 may include, for example, titanium silicon nitride (TiSiN), but the embodiments of the present disclosure are not limited thereto. As another example, the third lower electrode 313 may include tantalum silicon nitride (TaSiN) or tungsten silicon nitride (WSiN).

Each of the first lower electrode 311, the second lower electrode 312, and the third lower electrode 313 includes different materials from each other. Therefore, it is possible to reduce or prevent tilting and bending of the lower electrode structure 310 (e.g., as aspect ratio increases) and to ensure the capacitance of the lower electrode structure 310 at the same time, by the characteristics of the materials constituting each of the lower electrodes 311, 312, and 313. Accordingly, the performance and reliability of the semiconductor memory device may be improved.

Although the first lower electrode 311, the second lower electrode 312, and the third lower electrode 313 are each shown as a single film in FIG. 2, embodiments of the present disclosure are not limited thereto. As another example, at least one of the first lower electrode 311, the second lower electrode 312, and the third lower electrode 313 may include a multi-layer film.

A first support pattern 210, a second support pattern 220, and an upper support pattern 240 may be sequentially disposed on the etching stop film 105. The first support pattern 210 may be spaced apart from the etching stop film 105 in the third direction D3. The second support pattern 220 may be spaced apart from the first support pattern 210 in the third direction D3. The upper support pattern 240 may be disposed on a lower support pattern (not shown) and/or on the third lower electrode 313.

The number of the support patterns 210, 220 and 240 that support the lower electrode structure 310 may vary. For example, only the first support pattern 210 and the upper support pattern 240 may support the lower electrode structure 310. In the third direction D3, the relationship between the thickness of the first support pattern 210, the thickness of the second support pattern 220, and the thickness of the upper support pattern 240 may vary. The relationship between the distance between the etching stop film 105 and the first support pattern 210 and the distance between the first support pattern 210 and the second support pattern 220 may vary.

The first support pattern 210, the second support pattern 220, and the upper support pattern 240 may be sequentially disposed on and positioned spaced apart along the side wall of the lower electrode structure 310 to be spaced apart from each other. The first support pattern 210, the second support pattern 220, and the upper support pattern 240 may be in contact with a part or portion of the side wall of the lower electrode structure 310. The first support pattern 210, the second support pattern 220, and the upper support pattern 240 may connect adjacent lower electrode structures 310. In the drawings, groups of three lower electrode structures 310 are shown as being connected by the first support pattern 210, the second support pattern 220, and the upper support pattern 240, but embodiments are not limited thereto.

The upper support pattern 240 may be disposed on the upper face of the lower electrode structure 310 and the upper face of the capacitor dielectric film 320. Hereinafter, an upper face 313us of the third lower electrode 313 refers to the uppermost surface of the third lower electrode 313, which is opposite the storage pad 104.

The upper support pattern 240 may be in contact with the upper face of the lower electrode structure 310 and the upper face of the capacitor dielectric film 320. The upper support pattern 240 is shown to be in contact with the upper face 311us of the first lower electrode 311, but embodiments of the present disclosure are not limited thereto.

As another example, the upper support pattern 240 may not come into direct contact with the upper face 311us of the first lower electrode 311, but may be in contact with the upper face 313us of the third lower electrode 313. The upper face 240us of the upper support pattern 240 may be flat or substantially planar.

Hereinafter, a lower face 240ls of the upper support pattern 240 refers to a surface on which the upper support pattern 240 comes into contact with the capacitor dielectric film 320. The lower face 240ls of the upper support pattern 240 may be disposed below the upper face 313us of the third lower electrode 313. However, embodiments of the present disclosure are not limited thereto. As another example, the upper face 313us of the third lower electrode 313 may be disposed on the same plane as (i.e., coplanar with) the lower face 240ls of the upper support pattern 240.

Each of the first support pattern 210, the second support pattern 220, and the upper support pattern 240 may include at least one of, for example, silicon nitride (SiN), silicon carbonitride (SiCN), silicon boron nitride (SiBN), silicon carbonate (SiCO), silicon oxynitride (SiON), silicon oxide (SiO), and silicon oxycarbonitride (SiOCN).

The capacitor dielectric film 320 may be disposed on the lower electrode structure 310, the first support pattern 210, the second support pattern 220, and the upper support pattern 240. The capacitor dielectric film 320 may extend along a profile of (e.g., conformally along) the lower electrode structure 310, an upper face and a lower face of the first support pattern 210, an upper face and a lower face of the second support pattern 220, and an upper face 240us and a side face (and on portions of the lower face 240ls) of the upper support pattern 240.

The capacitor dielectric film 320 may include a high-dielectric constant material including, for example, silicon oxide, silicon nitride, silicon oxynitride, and metal. Although the capacitor dielectric film 320 is shown as a single film, this is only for convenience of explanation, and embodiments are not limited thereto.

An upper electrode 330 may be disposed on the capacitor dielectric film 320. The upper electrode 330 may extend along the profile of (e.g., conformally along) the capacitor dielectric film 320. The upper plate electrode 340 may be disposed on the upper electrode 330. The upper electrode 330 may be disposed between the capacitor dielectric film 320 and the upper plate electrode 340.

The upper electrode 330 may include, but not limited to, for example, a doped semiconductor material, a conductive metal nitride (e.g., titanium nitride, tantalum nitride, niobium nitride or tungsten nitride), a metal (e.g., ruthenium, iridium, titanium or tantalum), a conductive metal oxide (e.g., iridium oxide or niobium oxide), or the like.

An upper plate electrode 340 may include, for example, at least one of an elemental semiconductor material film or a compound semiconductor material film. The upper plate electrode 340 may include doped n-type impurities or p-type impurities.

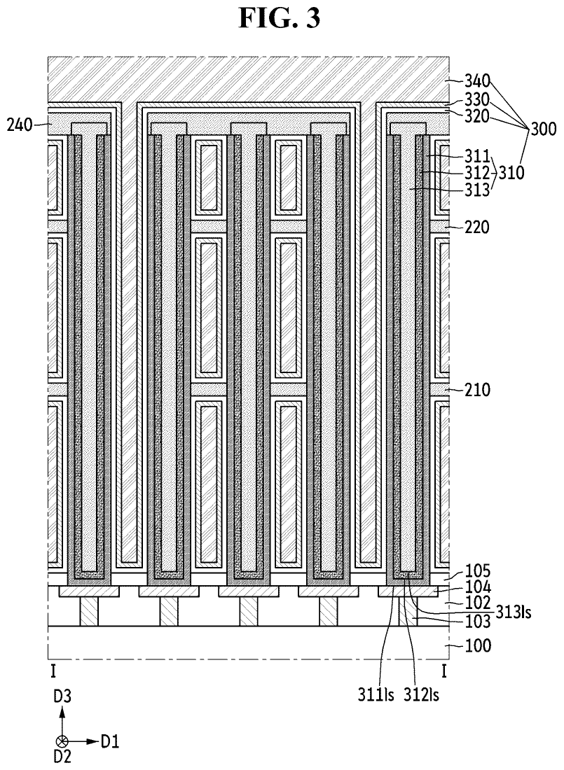

FIG. 3 is an example cross-sectional view taken along I-I of FIG. 1 according to some embodiments of the present disclosure. For convenience of explanation, differences from those explained in FIGS. 1 and 2 will be mainly explained in FIG. 3.

Referring to FIG. 3, the lower face 313ls of the third lower electrode 313 may come into direct contact with the second lower electrode 312. The lower face 313ls of the third lower electrode 313 may not come into direct contact with the first lower electrode 311. The lower face 313ls of the third lower electrode 313 may not come into direct contact with the storage pad 104. The third lower electrode 313 may be electrically connected to the storage pad 104 through the first lower electrode 311 and the second lower electrode 312.

Hereinafter, a lower face 311ls of the first lower electrode 311 refers to the lowermost surface of the first lower electrode 311. The lower face 311ls of the first lower electrode 311 may come into direct contact with the storage pad 104. The first lower electrode 311 comes into direct contact with the storage pad 104, and may be electrically connected to the storage pad 104.

Hereinafter, a lower face 312ls of the second lower electrode 312 refers to the lowermost surface of the second lower electrode 312. The lower face 312ls of the second lower electrode 312 may come into direct contact with the first lower electrode 311. The second lower electrode 312 may be electrically connected to the storage pad 104 through the first lower electrode 311.

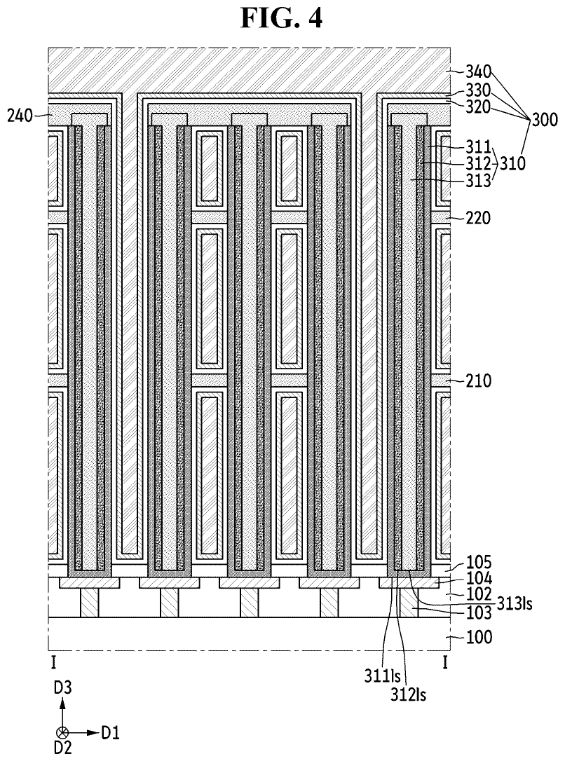

FIG. 4 is an example cross-sectional view taken along I-I of FIG. 1 according to some embodiments of the present disclosure. For convenience of explanation, differences from those explained in FIGS. 1 and 2 will be mainly explained in FIG. 4.

Referring to FIG. 4, a lower face 313ls of the third lower electrode 313 may come into direct contact with the first lower electrode 311. The lower face 313ls of the third lower electrode 313 may not come into direct contact with the second lower electrode 312. The third lower electrode 313 may be electrically connected to the storage pad 104 through the first lower electrode 311.

Hereinafter, the lower face 311ls of the first lower electrode 311 refers to the lowermost surface of the first lower electrode 311. The lower face 311ls of the first lower electrode 311 may come into direct contact with the storage pad 104. The first lower electrode 311 comes into direct contact with the storage pad 104, and may be electrically connected to the storage pad 104.

Hereinafter, the lower face 312ls of the second lower electrode 312 refers to the lowermost surface of the second lower electrode 312. The lower face 312ls of the second lower electrode 312 may not come into direct contact with the storage pad 104. The second lower electrode 312 may be electrically connected to the storage pad 104 through the first lower electrode 311.

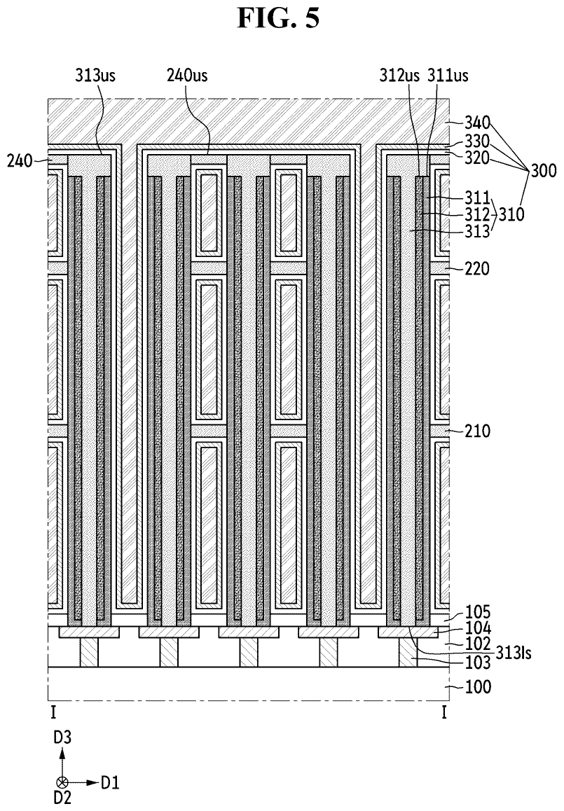

FIG. 5 is an example cross-sectional view taken along I-I of FIG. 1 according to some embodiments of the present disclosure. For convenience of explanation, differences from those explained in FIGS. 1 and 2 will be mainly explained in FIG. 5.

Referring to FIG. 5, the upper support pattern 240 may be in contact with the lower electrode structure 310. Specifically, the upper support pattern 240 may be in contact with the third lower electrode 313, and may not come into direct contact with the first lower electrode 311 and the second lower electrode 312.

An upper face 313us of the third lower electrode 313 may be disposed on the same plane as the upper face 240us of the upper support pattern 240. The upper face 240us of the upper support pattern 240 may include a flat or planar shape. In this example, the third lower electrode 313 may cover both the upper face 311us of the first lower electrode 311 and the upper face 312us of the second lower electrode 312.

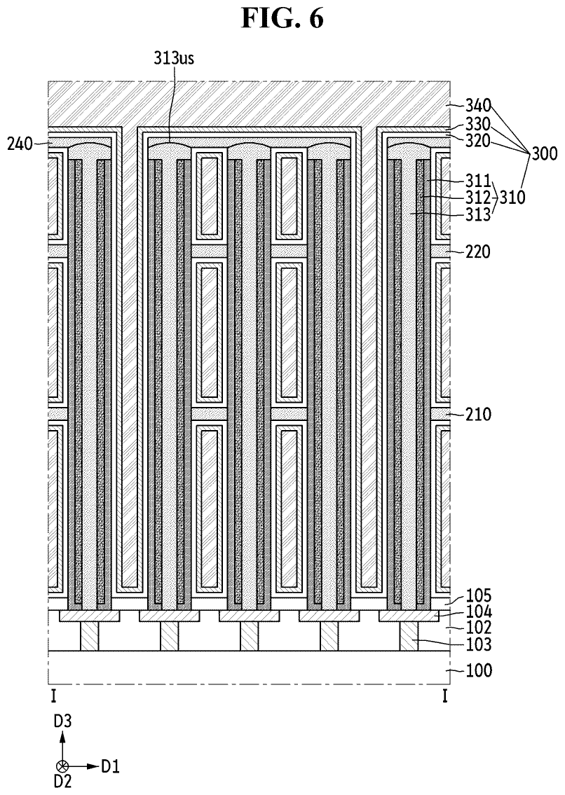

FIG. 6 is an example cross-sectional view taken along I-I of FIG. 1 according to some embodiments of the present disclosure. For convenience of explanation, differences from those explained in FIGS. 1 and 2 will be mainly explained in FIG. 6.

Referring to FIG. 6, the upper face 313us of the third lower electrode 313 may not be flat. The upper face 313us of the third lower electrode 313 may include a rounded shape. The upper face 313us of the third lower electrode 313 may include a convex shape away from the substrate 100 in the third direction D3.

The upper support pattern 240 may be in contact with the lower electrode structure 310. Specifically, the upper support pattern 240 may be in contact with the third lower electrode 313, and may not come into direct contact with the first lower electrode 311 and the second lower electrode 312.

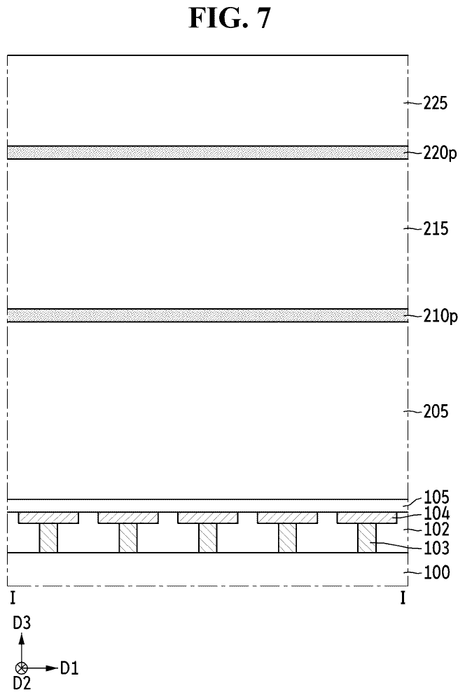

FIGS. 7 to 17 are intermediate stage diagrams for explaining a method for fabricating a semiconductor memory device according to some embodiments. For reference, FIGS. 7 to 17 are cross-sectional views taken along line I-I of FIG. 1. For convenience of description, differences from those explained using FIGS. 1 and 2 will be mainly explained.

Referring to FIG. 7, a storage contact 103 and a storage pad 104 may be formed in the interlayer insulating film 102 on the substrate 100.

A first mold film 205, a first support film 210p, a second mold film 215, a second support film 220p, and a third mold film 225 are sequentially formed on the interlayer insulating film 102. The first support film 210p may include a material having an etching selectivity with respect to the first mold film 205 and the second mold film 215. The second support film 220p may include a material having an etching selectivity with respect to the second mold film 215 and the third mold film 225. Each of the first to third mold films 205, 215, and 225 may have a single layer film structure or a multi-layer film structure including a plurality of different films from each other.

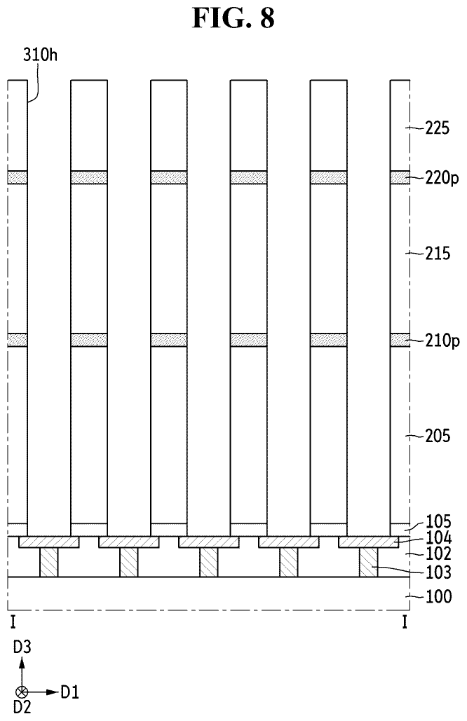

Referring to FIG. 8, a lower electrode hole 310h which penetrates the first mold film 205, the first support film 210p, the second mold film 215, the second support film 220p, and the third mold film 225 may be formed. An upper face of the storage pad 104 may be exposed by the lower electrode hole 310h. In some embodiments, the lower electrode hole 310h may have a constant horizontal width, and in some embodiments, the lower electrode hole 310h may have a tapered shape in which the horizontal width narrows from the top to the bottom.

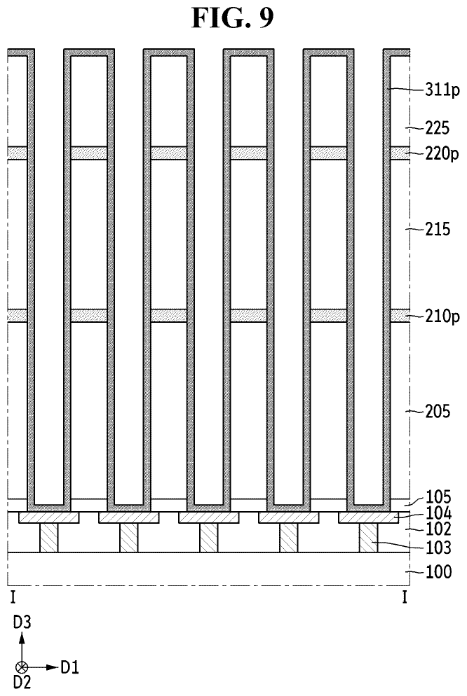

Referring to FIG. 9, a first lower electrode film 311p may be formed. The first lower electrode film 311p may be formed on the third mold film 225 and may fill (e.g., conformally) the lower electrode hole 310h. The term “fill” or “cover” or “surround” as may be used herein may not require completely filling or covering or surrounding the described elements or layers, but may, for example, refer to partially filling or covering or surrounding the described elements or layers, for example, with voids, spaces, or other discontinuities throughout. The first lower electrode film 311p may cover the upper face of the storage pad 104 exposed by the lower electrode hole 310h, and the third mold film 225. For example, the first lower electrode film 311p may be formed by a process such as a chemical vapor deposition (CVD), an atomic layer deposition (ALD) or a plasma enhanced ALD (PEALD).

A lower electrode film 311p may thereby be formed along the lower electrode hole 310h and the upper face of the third mold film 225. The lower electrode film 311p may be formed to conformally fill the lower electrode hole 310h. That is, the lower electrode film 311p may be formed along the profile of the lower electrode hole 310h.

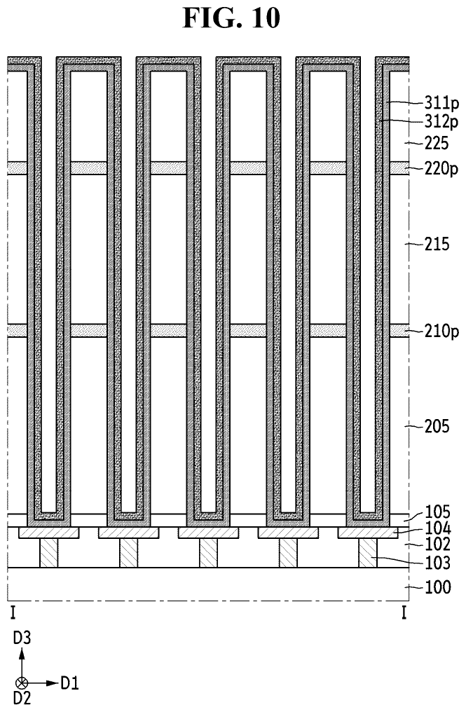

Referring to FIG. 10, a second lower electrode film 312p may be formed. The second lower electrode film 312p may be formed along the profile of the first lower electrode film 311p. The second lower electrode film 312p may be formed by a process such as a chemical vapor deposition, an atomic layer deposition or a PEALD.

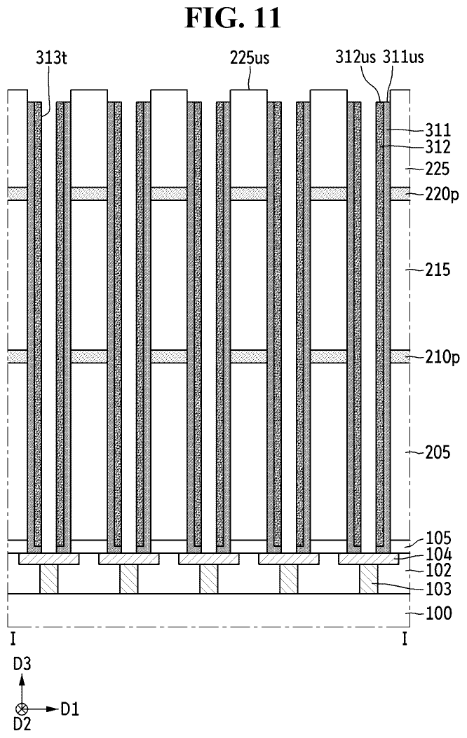

Referring to FIG. 11, a first lower electrode 311 may be formed, by removing a part of the upper part and a part of the lower part of the first lower electrode film 311p. A second lower electrode 312 may be formed, by removing a part of the upper part and a part of the lower part of the second lower electrode film 312p. A part of the lower part of the first lower electrode 311 and the second lower electrode 312 may be removed to expose the upper face of the storage pad 104. A part of the upper part and a part of the lower part of the first lower electrode 311 and the second lower electrode 312 may be removed by an etch-back process, respectively.

The upper face 311us of the first lower electrode 311, the upper face 312us of the second lower electrode 312, and the upper face 225us of the third mold film 225 may be coplanar, i.e., disposed on the same plane. The upper face 225us of the third mold film 225 may be disposed above the upper face 311us of the first lower electrode 311, relative to the substrate. The upper face 225us of the third mold film 225 may be disposed above the upper face 312us of the second lower electrode 312. A trench 313t may be formed inside the first lower electrode 311 and the second lower electrode 312.

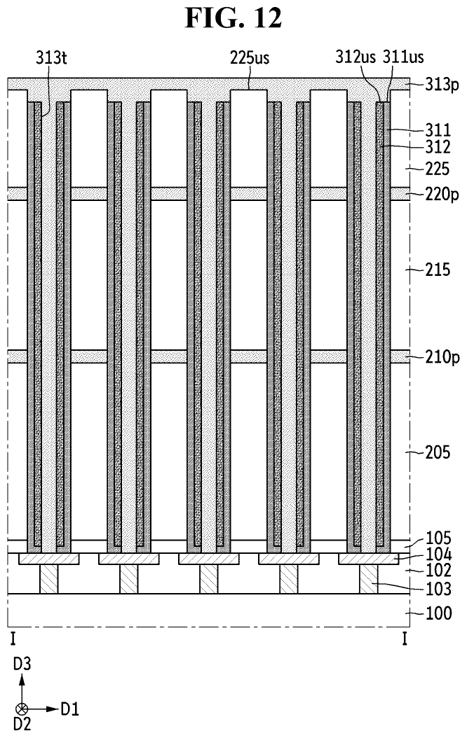

Referring to FIG. 12, a third lower electrode film 313p that fills the trench 313t may be formed. The third lower electrode film 313p may cover the upper face 311us of the first lower electrode 311, the upper face 312us of the second lower electrode 312, and the upper face 225us of the third mold film 225. The third lower electrode film 313p may be formed by a process such as a chemical vapor deposition, an atomic layer deposition or a PEALD.

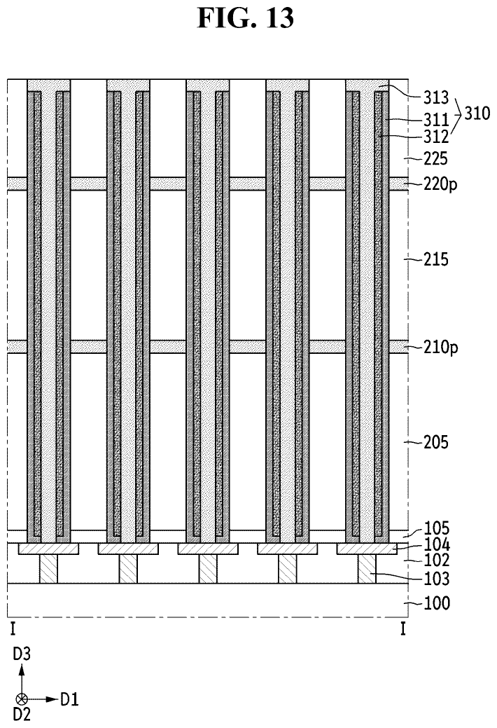

Referring to FIG. 13, the third lower electrode 313 may be formed by removing at least a part of the third lower electrode film 313p. The third lower electrode film 313p may be removed by a chemical mechanical polishing (CMP) process.

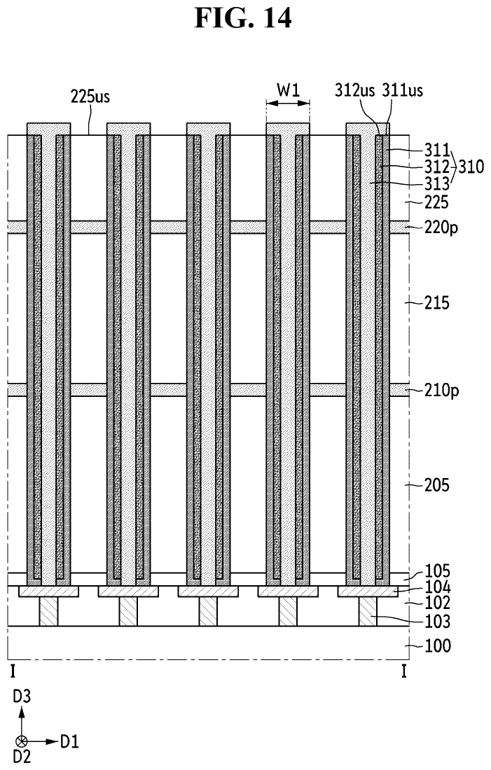

Referring to FIG. 14, a part of the third mold film 225 may be removed. A part of the third mold film 225 may be removed by an etch-back process. A part of the third mold film 225 is removed, and the upper face 311us of the first lower electrode 311 and the upper face 225us of the third mold film 225 may be disposed on the same plane. A part of the third mold film 225 is removed, and the upper face 312us of the second lower electrode 312 and the upper face 225us of the third mold film 225 may be disposed on the same plane.

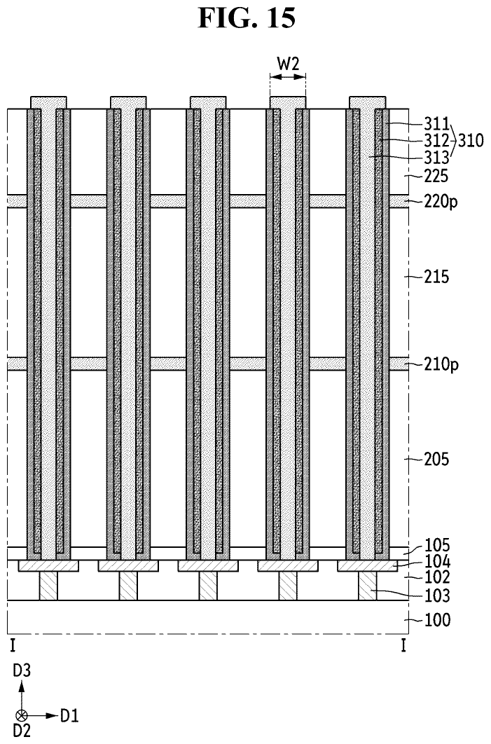

Referring to FIG. 15, the length of the upper face 313us of the third lower electrode 313 in the first direction D1 may change by a trimming process. The length of the upper face 313us of the third lower electrode 313 in the first direction D1 may change from a first length (see W1 of FIG. 14) to a second length W2. The first length W1 is longer than the second length W2. That is to say, the length of the upper face 313us of the third lower electrode 313 in the first direction D1 may decrease.

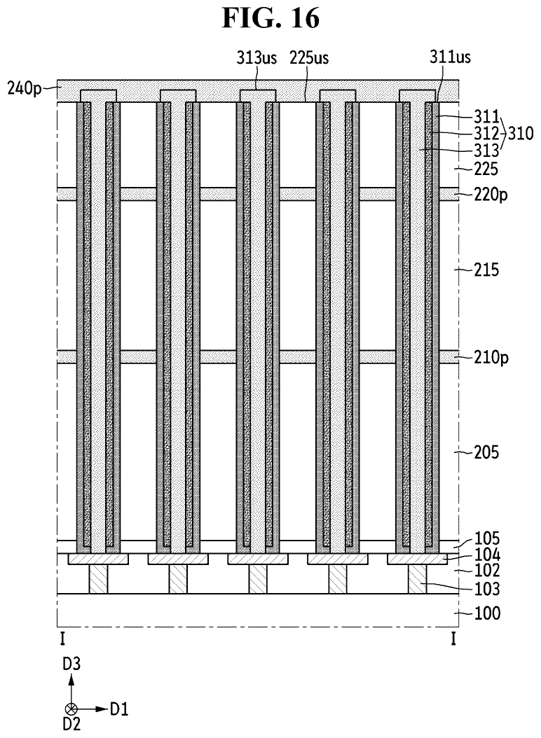

Referring to FIG. 16, an upper support film 240p that covers a part of the upper face 311us of the first lower electrode 311, the upper face 225us of the third mold film 225, and the upper face 313us of the third lower electrode 313 may be formed.

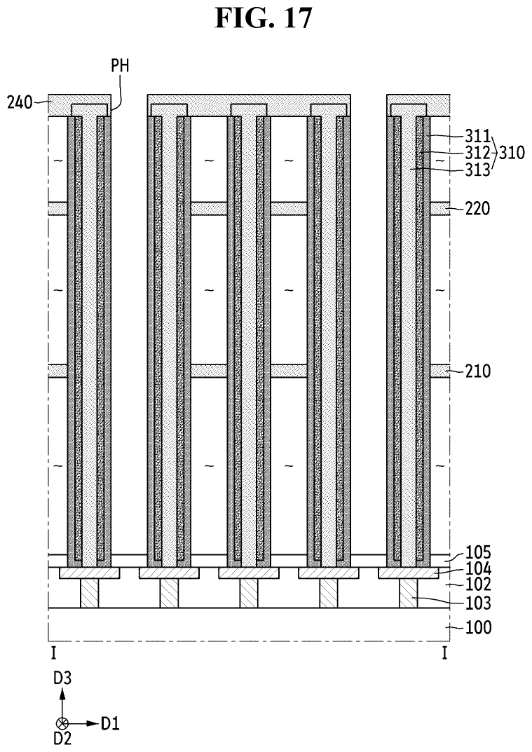

Referring to FIG. 17, through-holes PH which penetrate the first mold film 205, the first support film 210p, the second mold film 215, the second support film 220p, the third mold film 225, the lower support film (not shown), and the upper support film 240p of FIG. 16 may be formed.

A partial outer wall of the lower electrode structure 310 and the upper face of the etching stop film 105 may be exposed by the through-holes PH. Accordingly, the first support pattern 210, the second support pattern 220, and the upper support pattern 240 may be formed. Each of the first support pattern 210, the second support pattern 220, and the upper support pattern 240 may be the first support film 210p, the second support film 220p, and the upper support film 240p that remain without being etched.

The first to third mold films 205, 215 and 225 exposed by the through-holes PH may be removed. For example, the first to third mold films 205, 215 and 225 may be removed by a wet etching process. Accordingly, the lower electrode structure 310, the first support pattern 210, the second support pattern 220, and the upper support pattern 240 may be exposed.

Referring to FIG. 2, a capacitor dielectric film 320 which extends along the exposed lower electrode structure 310, the first support pattern 210, the second support pattern 220, and the upper support pattern 240 may be formed. The capacitor dielectric film 320 may be formed on the upper and lower faces of the first support pattern 210, the upper and lower faces of the second support pattern 220, the upper and side faces of the upper support pattern 240, and the upper face of the etching stop film 105.

The upper electrode 330 may be formed on the capacitor dielectric film 320. An upper plate electrode 340 may be formed on the upper electrode 330. While the upper plate electrode 340 is formed, a part of the upper electrode 330 may be patterned to correspond to the size of the upper plate electrode 340. The upper electrode 330 and the upper plate electrode 340 may fill the gap between the etching stop film 105 and the first support pattern 210, between the first support pattern 210 and the second support pattern 220, between the second support pattern 220 and the upper support pattern 240, and the through-hole PH.

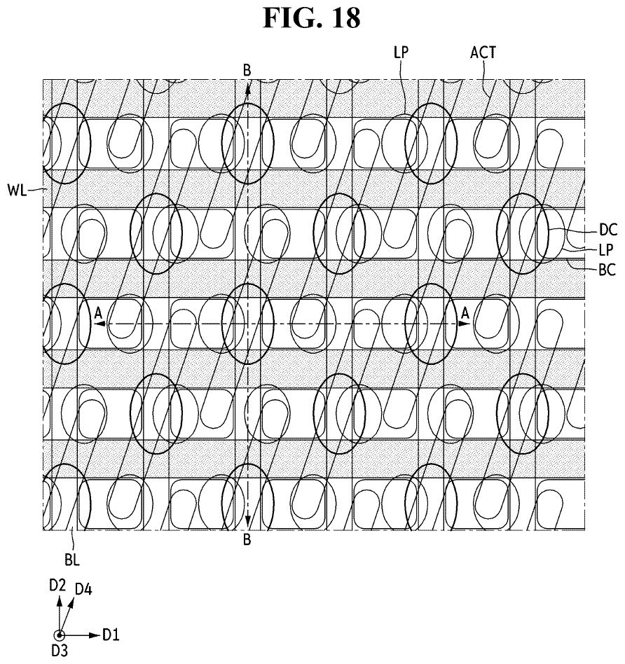

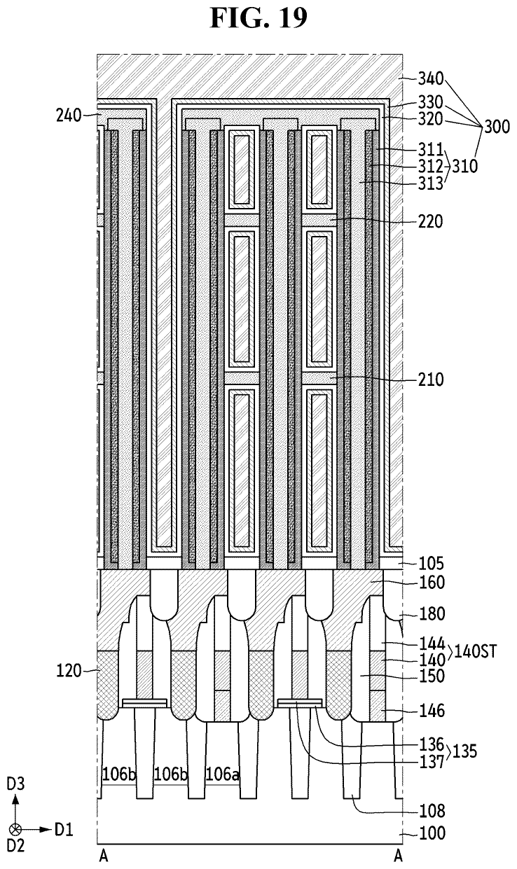

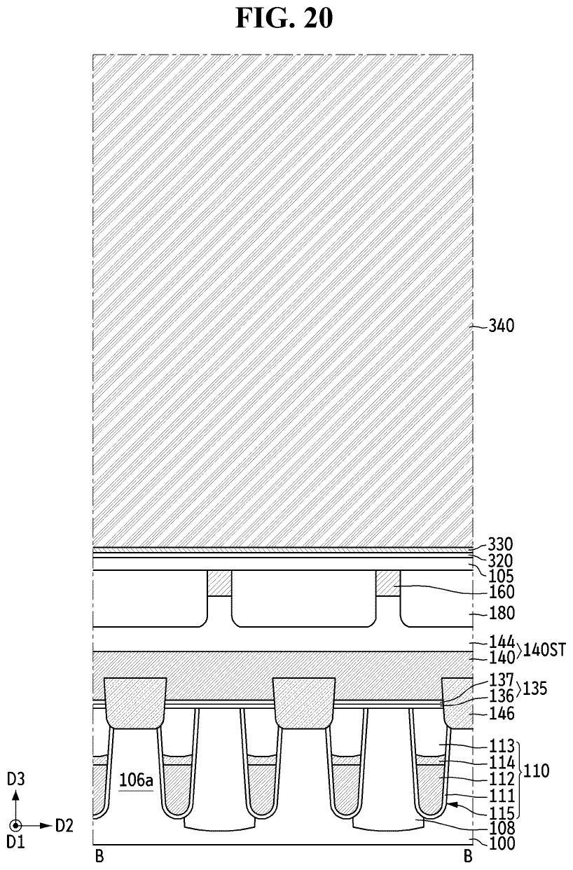

FIGS. 18 to 20 are diagrams for explaining a semiconductor memory device according to some embodiments. For reference, FIG. 18 is a schematic layout for explaining a semiconductor memory device according to some embodiments. FIG. 19 is a cross-sectional view taken along line A-A of FIG. 18. FIG. 20 is a cross-sectional view taken along line B-B of FIG. 18. For convenience of explanation, differences from those explained using FIGS. 1 and 2 will be mainly explained.

Referring to FIGS. 18 to 20, the semiconductor memory device according to some embodiments may include a plurality of cell active regions ACT.

The cell active region ACT may be defined by a cell element isolation film 108 formed in the substrate 100. As the design rule of the semiconductor memory device decreases, the cell active region ACT may be disposed in the form of a bar of a diagonal line or an oblique line, as shown. For example, the cell active region ACT may extend in a fourth direction D4. Hereinafter, the fourth direction D4 is a direction between the first direction D1 and the second direction D2, aligned with (e.g., parallel to) the upper face of the substrate 100.

A plurality of gate electrodes which extend in the first direction D1 across the cell active region ACT may be disposed. The plurality of gate electrodes may extend parallel to each other. The plurality of gate electrodes may be, for example, a plurality of word lines WL. The word lines WL may be disposed at equal intervals. The width of the word lines WL or the interval between the word lines WL may be determined depending on the design rule.

Each cell active region ACT may be divided into three portions by two word lines WL extending in the first direction D1. The cell active region ACT may include a storage connecting region 106b and a bit line connecting region 106a. The bit line connecting region 106a may be located in the central portion of the cell active region ACT, and the storage connecting region 106b may be located at the end part of the cell active region ACT.

For example, the bit line connecting region 106a may be a region connected to the bit line BL, and the storage connecting region 106b may be a region connected to the capacitor structure 300. In other words, the bit line connecting region 106a may correspond to a common drain region, and the storage connecting region 106b may correspond to a source region. Each word line WL, and the bit line connecting region 106a and storage connecting region 106b adjacent thereto may form a transistor.

A plurality of bit lines BL extending in the second direction D2 orthogonal to the word line WL may be disposed on the word line WL. The plurality of bit lines BL may extend to be parallel to each other. The bit lines BL may be disposed at regular intervals. A width of the bit lines BL or an interval between the bit lines BL may be determined depending on design rules.

The semiconductor memory device according to some embodiments may include various contact arrangements formed on the cell active region ACT. Various contact arrangements may include, for example, a direct contact DC, a buried contact BC, a landing pad LP, and the like.

Here, the direct contact DC may mean a contact that electrically connects the cell active region ACT to the bit line BL. The buried contact BC may mean a contact that connects the cell active region ACT to a lower electrode structure 310 of the capacitor structure 300. A contact area between the buried contact BC and the cell active region ACT may be relatively small due to the placement structure. Therefore, a conductive landing pad LP may be introduced to enlarge the contact area with the cell active region ACT and enlarge the contact area with the lower electrode structure 310.

The landing pad LP may be disposed between the cell active region ACT and the buried contact BC, or may be disposed between the buried contact BC and the lower electrode structure 310. In the semiconductor memory device according to some embodiments, the landing pad LP may be disposed between the buried contact BC and the lower electrode structure 310. By enlarging the contact area through the introduction of the landing pad LP, the contact resistance between the cell active region ACT and the lower electrode structure 310 of the capacitor structure 300 may decrease.

The direct contact DC may be connected to the bit line connecting region 106a. The buried contact BC may be connected to the storage connecting region 106b. As the buried contact BC is disposed at both or opposing end portions of the cell active region ACT, the landing pad LP may be disposed adjacent to both or opposing ends of the cell active region ACT to partially overlap the buried contact BC. In other words, the buried contact BC may be formed to overlap the cell active region ACT and the cell element isolation film 108 between the adjacent word lines WL and between the adjacent bit lines BL.

The word line WL may be formed as a structure buried inside the substrate 100. The word line WL may be disposed across the cell active region ACT between the direct contact DC and the buried contact BC. As shown, two word lines WL may be disposed to cross one active region ACT. Since the cell active region ACT extends along the fourth direction D4, the word line WL may have an angle less than 90 degrees with the cell active region ACT.

The direct contact DC and the buried contact BC may be disposed symmetrically. Therefore, the direct contact DC and the buried contact BC may be disposed on a straight line along the first direction D1 and the third direction D2. Meanwhile, unlike the direct contact DC and the buried contact BC, the landing pads LP may be disposed in a zigzag manner in the second direction D2 in which the bit line BL extends. Also, the landing pads LP may be disposed to overlap the same side face portions of each bit line BL in the first direction D1 in which the word line WL extends. Components or layers described with reference to “overlap” in a particular direction may be at least partially obstructed by one another when viewed along a line extending in the particular direction or in a plane perpendicular to the particular direction. For example, each of the landing pads LP of the first line may overlap a left side of the corresponding bit line BL, and each of the landing pads LP of the second line may overlap a right side of the corresponding bit line BL.

The semiconductor memory device according to some embodiments may include a plurality of cell gate structures 110, a plurality of bit line structures 140ST, a plurality of node connecting pads (not shown), a plurality of bit line contacts 146, and a capacitor structure 300.

The cell element isolation film 108 may be formed in the substrate 100. The cell element isolation film 108 may have a shallow trench isolation (STI) structure having excellent element isolation characteristics. The cell element isolation film 108 may define a cell active region ACT in the memory cell region.

The cell active region ACT defined by the cell element isolation film 108 may have a long or elongated island formation including a short axis and a long axis. The cell active region ACT may have an oblique line shape to have an angle of less than 90 degrees with respect to the word line WL formed in the cell element isolation film 108. Further, the cell active region ACT may have an oblique line shape to have an angle of less than 90 degrees with respect to the bit line BL formed on the cell element isolation film 108.

The cell element isolation film 108 may include, but is not limited to, at least one of a silicon oxide film, a silicon nitride film, and a silicon oxynitride film. Although the cell element isolation film 108 is shown to be formed of one insulating film, this is only for convenience of explanation, and embodiments are not limited thereto. Depending on the spaced distance between adjacent cell active regions ACT, the cell element isolation film 108 may be formed of one insulating film or may be formed of a plurality of insulating films.

Although the upper face of the cell element isolation film 108 and the upper face of the substrate 100 are shown as being disposed on the same plane, this is only for convenience of explanation, and embodiments are not limited thereto.

The cell gate structure 110 may be formed inside the substrate 100 and the cell element isolation film 108. The cell gate structure 110 may be formed across the cell element isolation film 108, and the cell active region ACT defined by the cell element isolation film 108.

The cell gate structure 110 is formed in the substrate 100 and the cell element isolation film 108. The cell gate structure 110 may include a cell gate trench 115, a cell gate insulating film 111, a cell gate electrode 112, a cell gate capping pattern 113, and a cell gate capping conductive film 114.

Here, the cell gate electrode 112 may correspond to the word line WL. Unlike the shown example, the cell gate structure 110 may not include the cell gate capping conductive film 114 in some embodiments.

Although not shown, the cell gate trench 115 may be relatively deep in the cell element isolation film 108 and relatively shallow in the cell active region ACT. A bottom face of the word line WL may be curved. That is, the depth of the cell gate trench 115 in the cell element isolation film 108 may be greater than the depth of the cell gate trench 115 in the cell active region ACT.

The cell gate insulating film 111 may extend along the side wall and the bottom face of the cell gate trench 115. The cell gate insulating film 111 may extend along the profile of at least a part of the cell gate trench 115.

The cell gate insulating film 111 may include, for example, at least one of silicon oxide, silicon nitride, silicon oxynitride or a high dielectric constant material having a higher dielectric constant than that of silicon oxide. The high-dielectric constant material may include, for example, at least one of boron nitride, hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, lead zinc niobate, and combinations thereof.

The cell gate electrode 112 may be disposed on the cell gate insulating film 111. The cell gate electrode 112 may fill a part of the cell gate trench 115. The cell gate capping conductive film 114 may extend along an upper face of the cell gate electrode 112.

The cell gate electrode 112 may include at least one of a metal, a metal alloy, a conductive metal nitride, a conductive metal carbonitride, a conductive metal carbide, a conductive metal silicide, a doped semiconductor material, a conductive metal oxynitride, and a conductive metal oxide. The cell gate electrode 112 may include, for example, but is not limited to, at least one of TiN, TaC, TaN, TiSiN, TaSiN, TaTiN, TiAlN, TaAlN, WN, Ru, TiAl, TiAlC—N, TiAlC, TiC, TaCN, W, Al, Cu, Co, Ti, Ta, Ni, Pt, Ni—Pt, Nb, NbN, NbC, Mo, MoN, MoC, WC, Rh, Pd, Ir, Ag, Au, Zn, V, RuTiN, TiSi, TaSi, NiSi, CoSi, IrO, RuO and combinations thereof.

The cell gate capping conductive film 114 may include, but not limited to, for example, one of polysilicon, polysilicon-germanium, amorphous silicon, and amorphous silicon-germanium.

The cell gate capping pattern 113 may be disposed on the cell gate electrode 112 and the cell gate capping conductive film 114. The cell gate capping pattern 113 may fill the cell gate trench 115 that remains after the cell gate electrode 112 and the cell gate capping conductive film 114 are formed. The cell gate insulating film 111 is shown to extend along the side wall of the cell gate capping pattern 113, but is not limited thereto.

The cell gate capping pattern 113 may include, for example, at least one of silicon nitride, silicon oxynitride, silicon oxide, silicon carbonitride, silicon oxycarbonitride, and combinations thereof.

The upper face of the cell gate capping pattern 113 is shown to be coplanar with the upper face of the cell element isolation film 108, but is not limited thereto.

Although not shown, an impurity doping region may be formed on at least one side of the cell gate structure 110. The impurity doping region may be a source/drain region of a transistor. The impurity doping region may be formed in the storage connecting region 106b and the bit line connecting region 106a.

The bit line structure 140ST may include a cell conductive line 140 and a cell line capping film 144. The cell conductive line 140 may be disposed on the substrate 100 and the cell element isolation film 108 on which the cell gate structure 110 is formed. The cell conductive line 140 may intersect the cell element isolation film 108, and the cell active region ACT defined by the cell element isolation film 108. The cell conductive line 140 may be formed to cross the cell gate structure 110. Here, the cell conductive line 140 may correspond to the bit line BL.

The cell conductive line 140 may include, for example, at least one of a semiconductor material doped with impurities, a conductive metal silicide, a conductive metal nitride, a conductive metal oxide, a two-dimensional material (2D material), a metal, and a metal alloy. In the semiconductor memory device according to some embodiments, the two-dimensional material may be a metallic material and/or a semiconductor material. The two-dimensional material (2D material) may include a two-dimensional allotrope or a two-dimensional compound, and may include, for example, at least one of graphene, molybdenum disulfide (MoS₂), molybdenum diselenide (MoSe₂), tungsten diselenide (WSe₂), and tungsten disulfide (WS₂), but embodiments are not limited thereto. That is, the above-mentioned two-dimensional materials are merely listed as examples, and the two-dimensional materials that may be included in the semiconductor memory device of the present disclosure are not limited to the above-mentioned materials.

Although the cell conductive line 140 is shown as a single film, this is only for convenience of explanation, and embodiments are not limited thereto. That is, unlike the shown example, the cell conductive line 140 may include a plurality of conductive films in which the conductive materials are stacked in some embodiments.

The cell line capping film 144 may be disposed on the cell conductive line 140. The cell line capping film 144 may extend in the second direction D2 along the upper face of the cell conductive line 140. The cell line capping film 144 may include, for example, at least one of a silicon nitride film, a silicon oxynitride, a silicon carbonitride, and a silicon oxycarbonitride.

In the semiconductor memory device according to some embodiments, the cell line capping film 144 may include a silicon nitride film. Although the cell line capping film 144 is shown as being a single film, embodiments are not limited thereto.

A bit line contact 146 may be formed between the cell conductive line 140 and the substrate 100. The cell conductive line 140 may be disposed on the bit line contact 146.

The bit line contact 146 may be disposed between the cell conductive line 140 and the substrate 100. The cell conductive line 140 may be disposed on the bit line contact 146. The bit line contact 146 may be formed between the bit line connecting region 106a of the cell active region ACT and the cell conductive line 140. The bit line contact 146 may be connected to the bit line connecting region 106a.

The bit line contact 146 may electrically connect the cell conductive line 140 and the substrate 100. Here, the bit line contact 146 may correspond to a direct contact DC. The bit line contact 146 may include, for example, at least one of a semiconductor material doped with impurities, a conductive metal silicide, a conductive metal nitride, a conductive metal oxide, a metal, and a metal alloy.

The cell insulating film 135 may be formed on the substrate 100 and the cell element isolation film 108. More specifically, the cell insulating film 135 may be disposed on the substrate 100 and the cell element isolation film 108 on which the bit line contact 146 is not formed. The cell insulating film 135 may be disposed between the substrate 100 and the cell conductive line 140, and between the cell element isolation film 108 and the cell conductive line 140.

Although the cell insulating film 135 may be a single film, as shown, the cell insulating film 135 may be a multi-layer film including a first cell insulating film 136 and a second cell insulating film 137. For example, although the first cell insulating film 136 may include a silicon oxide film, and the second cell insulating film 137 may include a silicon nitride film, embodiments are not limited thereto. The cell insulating film 137 may include three or more insulating films, unlike those shown in the drawings, in some embodiments.

A storage contact 120 may be disposed between adjacent cell conductive lines 140 in the first direction D1. The storage contact 120 may overlap the substrate 100 and the cell element isolation film 108 between the adjacent cell conductive lines 140. The storage contact 120 may be connected to the storage connecting region 106b of the cell active region ACT. Here, the storage contact 120 may correspond to the buried contact BC. Also, the storage contact 120 may correspond to the storage contact 103 of FIGS. 1 to 6.

The storage contact 120 may include, for example, at least one of a semiconductor material doped with impurities, a conductive metal silicide, a conductive metal nitride, a conductive metal carbide, a conductive metal carbonitride, a conductive metal oxide, a metal, and a metal alloy.

A storage pad 160 may be disposed on the storage contact 120. The storage pad 160 may be electrically connected to the storage contact 120. Here, the storage pad 160 may correspond to the landing pad LP. Also, the storage pad 160 may correspond to the storage pad 104 of FIGS. 1 to 6.

The storage pad 160 may overlap a part of the upper face of the bit line structure 140ST in a vertical direction (e.g., D3). The storage pad 160 may include, for example, at least one of a semiconductor material doped with impurities, a conductive silicide compound, a conductive metal nitride, a conductive metal carbide, a metal, and a metal alloy.

A pad isolation insulating film 180 may be formed on the storage pad 160 and the bit line structure 140ST. For example, the pad isolation insulating film 180 may be disposed on the cell line capping film 144. The pad isolation insulating film 180 may define the storage pad 160 that forms or is provided between a plurality of isolation regions.

The pad isolation insulating film 180 does not cover the upper face of the storage pad 160. The pad isolation insulating film 180 may fill the pad isolation recess. The pad isolation recess may separate the adjacent storage pads 160. For example, the upper face of the storage pad 160 may be coplanar with the upper face of the pad isolation insulating film 180.

The pad isolation insulating film 180 may include an insulating material, and may electrically isolate the plurality of storage pads 160 from each other. For example, the pad isolation insulating film 180 may include, but not limited to, at least one of a silicon oxide film, a silicon nitride film, a silicon oxynitride film, a silicon oxycarbonitride film, and a silicon carbonitride film.

The etching stop film 105 may be disposed on the storage pad 160 and the pad isolation insulating film 180. The capacitor structure 300 may be disposed on the storage pad 160. The capacitor structure 300 may be electrically connected to the storage pad 160. The capacitor structure 300 may correspond to the capacitor structure 300 of FIGS. 2 to 6.

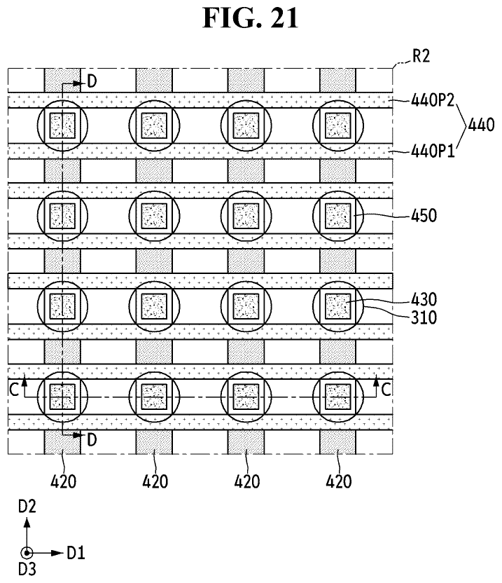

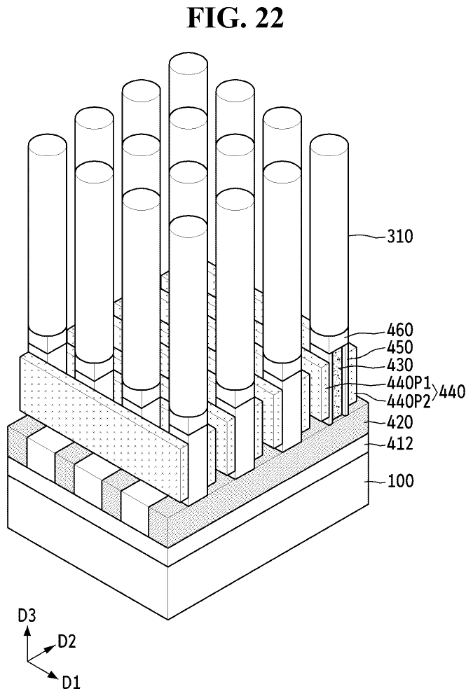

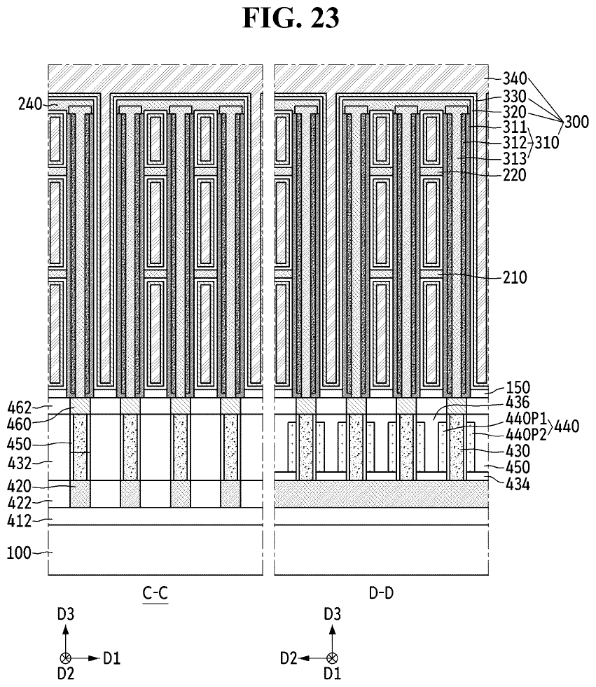

FIG. 21 is a layout diagram for explaining a semiconductor memory device according to some embodiments. FIG. 22 is a perspective view for explaining the semiconductor memory device according to some embodiments. FIG. 23 is a cross-sectional view taken along C-C and D-D of FIG. 21.

Referring to FIGS. 21 to 23, the semiconductor memory device according to some embodiments may include a substrate 100, a plurality of first conductive lines 420, a channel layer 430, a gate electrode 440, a gate insulating film 450, and a capacitor structure 300. The semiconductor memory device according to some embodiments may be a memory device including a vertical channel transistor VCT. The vertical channel transistor may refer to a structure in which the channel length of the channel layer 430 extends along a vertical direction (e.g., D3) from the substrate 100.

A lower insulating layer 412 may be disposed on the substrate 100. A plurality of first conductive lines 420 may be spaced apart from each other on the lower insulating layer 412 in the first direction D1, and extend in the second direction D2. A plurality of first insulating patterns 422 may be disposed on the lower insulating layer 412 to fill spaces between the plurality of first conductive lines 420. The plurality of first insulating patterns 422 may extend in the second direction D2. The upper faces of the plurality of first insulating patterns 422 may be disposed at the same level as (e.g., coplanar with) the upper faces of the plurality of first conductive lines 420. The plurality of first conductive lines 420 may function as bit lines.

The plurality of first conductive lines 420 may include a doped semiconductor material, a metal, a conductive metal nitride, a conductive metal silicide, a conductive metal oxide or combinations thereof. For example, the plurality of first conductive lines 420 may be made up of, but not limited to, doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOx, RuOx or a combination thereof. The plurality of first conductive lines 420 may include a single layer or multi-layers of the above-mentioned materials. In some embodiments, the plurality of first conductive lines 420 may include graphene, carbon nanotube or a combination thereof.

The channel layers 430 may be arranged in the form of a matrix in which they are disposed on the plurality of first conductive lines 420 to be spaced apart from each other in the first direction D1 and the second direction D2. The channel layer 430 may have a first width along the first direction D1 and a first height along the third direction D3, and the first height may be greater than the first width. For example, the first height may be, but not limited to, about 2 to 10 times the first width. A bottom portion of the channel layer 430 may function as a third source/drain region (not shown), an upper portion of the channel layer 430 may function as a fourth source/drain region (not shown), and a part of the channel layer 430 between the third and fourth source/drain regions may function as a channel region (not shown).

In the example embodiments, the channel layer 430 may include an oxide semiconductor, and the oxide semiconductor may include, for example, InₓGa_{y}Zn_{z}O, InₓGa_{y}Si_{z}O, InₓSn_{y}Zn_{z}O, InₓZn_{y}O, ZnₓO, ZnₓSn_{y}O, ZnₓO_{y}N, ZrₓZn_{y}Sn_{z}O, SnₓO, HfₓIn_{y}Zn_{z}O, GaₓZn_{y}Sn_{z}O, AlₓZn_{y}Sn_{z}O, YbₓGa_{y}Zn_{z}O, InₓGa_{y}O or combinations thereof. The channel layer 430 may include a single layer or multi-layers of the oxide semiconductor. In some embodiments, the channel layer 430 may have a bandgap energy that is greater than the bandgap energy of silicon. For example, the channel layer 430 may have a bandgap energy of about 1.5 eV to 5.6 eV. For example, the channel layer 430 may have optimum channel performance when having the bandgap energy of about 2.0 eV to 4.0 eV. For example, the channel layer 430 may be, but not limited to, polycrystalline or amorphous. In example embodiments, the channel layer 430 may include a silicon-based semiconductor material. The channel layer 430 may include graphene, carbon nanotube or a combination thereof.

The gate electrode 440 may extend in the first direction D1 on both or opposing side walls of the channel layer 430. The gate electrode 440 may include a first sub-gate electrode 440P1 that faces a first side wall of the channel layer 430, and a second sub-gate electrode 440P2 that faces a second side wall opposite to the first side wall of the channel layer 430. As the single channel layer 430 is disposed between the first sub-gate electrode 440P1 and the second sub-gate electrode 440P2, the semiconductor memory device may have a dual gate transistor structure. However, the technical idea of the present disclosure is not limited thereto, the second sub-gate electrode 440P2 may be omitted, and only the first sub-gate electrode 440P1 that faces the first side wall of the channel layer 430 may be formed to realize a single gate transistor structure. The materials included in the gate electrode 440 may be the same as description of the cell gate electrode 112.

The gate insulating film 450 surrounds the side walls of the channel layer 430, and may be interposed between the channel layer 430 and the gate electrode 440. For example, as shown in FIG. 19, the entire side wall of the channel layer 430 may be surrounded by the gate insulating film 450, and a part of the side wall of the gate electrode 440 may be in contact with the gate insulating film 450. In some embodiments, the gate insulating film 450 extends in the extending direction (i.e., the first direction D1) of the gate electrode 440, and only the two side walls that face the gate electrode 440 among the side walls of the channel layer 430 may be in contact with the gate insulating film 450. In the example embodiments, the gate insulating film 450 may be made up of a silicon oxide film, a silicon oxynitride film, a high dielectric constant material having a higher dielectric constant than the silicon oxide film, or a combination thereof.

A plurality of second insulating patterns 432 may extend on the plurality of first insulating patterns 422 along the second direction D2. The channel layer 430 may be disposed between two adjacent second insulating patterns 432 among the plurality of second insulating patterns 432. Further, the first buried layer 434 and the second buried layer 436 may be disposed in a space between two adjacent channel layers 430, between two adjacent second insulating patterns 432. The first buried layer 434 may be disposed at the bottom portion of the space between two adjacent channel layers 430. The second buried layer 436 may be formed to fill the remainder of the space between two adjacent channel layers 430 on the first buried layer 434. The upper face of the second buried layer 436 may be disposed at the same level as (e.g., coplanar with) the upper face of the channel layer 430, and the second buried layer 436 may cover the upper face of the gate electrode 440. In contrast, the plurality of second insulating patterns 432 may be formed of a continuous material layer with the plurality of first insulating patterns 422, or the second buried layer 436 may be formed of a continuous material layer with the first buried layer 434.

Capacitor contacts 460 may be disposed on the channel layer 430. The capacitor contacts 460 are disposed to vertically overlap the channel layer 430, and may be arranged in the form of a matrix in which they are spaced apart from each other in the first direction D1 and the second direction D2. The capacitor contacts 460 may be made up of, but not limited to, doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOx, RuOx or a combination thereof. An upper insulating film 462 may surround the side walls of the capacitor contacts 460 on the plurality of second insulating patterns 432 and the second buried layer 436.

The etching stop film 105 may be disposed on the upper insulating layer 462. The capacitor structure 300 may be disposed on the etching stop film 105. Each of the etching stop film 105 and the capacitor structure 300 may correspond to the etching stop film 105 and the capacitor structure 300 of FIGS. 2 to 6.

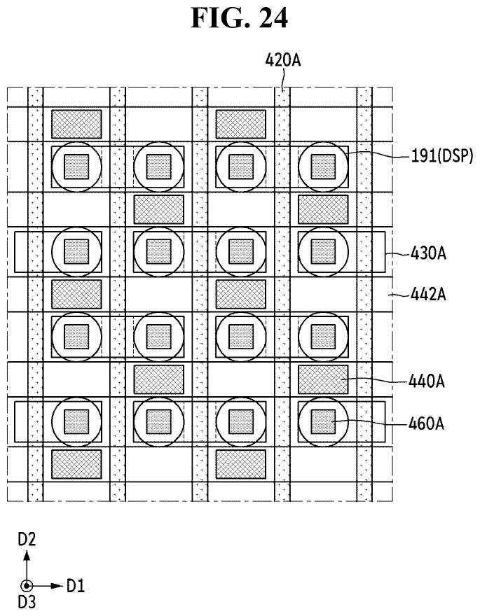

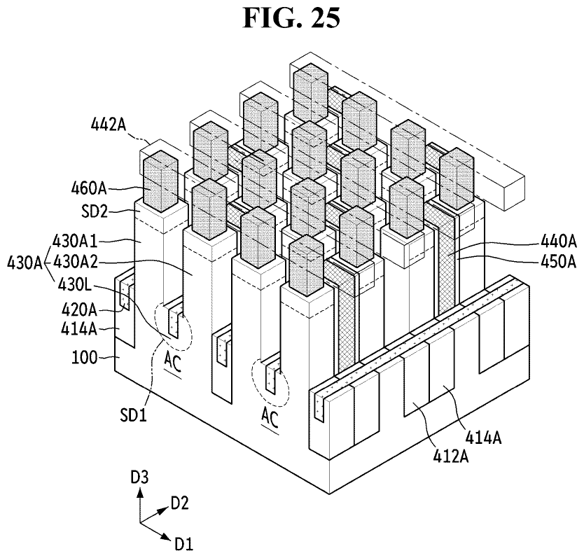

FIG. 24 is a layout diagram for explaining a semiconductor memory device according to some embodiments. FIG. 25 is a perspective view for explaining a semiconductor memory device according to some embodiments.

Referring to FIGS. 24 and 25, the semiconductor memory device according to some embodiments may include a substrate 100, a plurality of first conductive lines 420A, a channel structure 430A, a contact gate electrode 440A, a plurality of second conductive lines 442A, and a capacitor structure 300 (not shown in FIGS. 24 and 25). The semiconductor memory device according to some embodiments may be a memory device including a vertical channel transistor VCT.

A plurality of active regions AC may be defined in the substrate 100 by the first element isolation pattern 412A and the second element isolation pattern 414A. The channel structure 430A may be disposed in each active region AC. Each of the channel structure 430A may include a first active pillar 430A1 and a second active pillar 430A2 extending in a vertical direction, and a connecting part 430L connected to a bottom portion of the first active pillar 430A1 and a bottom portion of the second active pillar 430A2. A first source/drain region SD1 may be disposed in the connecting part 430L. A second source/drain region SD2 may be disposed on the upper side of the first and second active pillars 430A1 and 430A2. Each of the first active pillar 430A1 and the second active pillar 430A2 may constitute an independent unit memory cell.

The plurality of first conductive lines 420A may extend in a direction intersecting each of the plurality of active regions AC, and may extend, for example, in the second direction D2. One first conductive line 420A of the plurality of first conductive lines 420A may be disposed on the connecting part 430L between the first active pillar 430A1 and the second active pillar 430A2. One first conductive line 420A may be disposed on the first source/drain region SD1. The other first conductive line 420A adjacent to one first conductive line 420A may be disposed between the two channel structures 430A. One first conductive line 420A of the plurality of first conductive lines 420A may function as a common bit line included in two unit memory cells constituted by the first active pillar 430A1 and the second active pillar 430A2 disposed on both or opposing sides of the one first conductive lines 420A.

One contact gate electrode 440A may be disposed between two channel structures 430A adjacent to each other in the second direction D2. For example, the contact gate electrode 440A may be disposed between the first active pillar 430A1 included in one channel structure 430A and the second active pillar 430A2 of the channel structure 430A adjacent thereto. One contact gate electrode 440A may be shared by the first active pillar 430A1 and the second active pillar 430A2 disposed on both or opposing side walls thereof. A gate insulating film 450A may be disposed between the contact gate electrode 440A and the first active pillar 430A1, and between the contact gate electrode 440A and the second active pillar 430A2. The plurality of second conductive lines 442A may extend in the first direction D1 on the upper face of the contact gate electrode 440A. The plurality of second conductive lines 442A may function as word lines of the semiconductor memory device.

A capacitor contact 460A may be disposed on the channel structure 430A. The capacitor contact 460A may be disposed on the second source/drain region SD2, and the capacitor structure 300 may be disposed on the capacitor contact 460A. The capacitor structure 300 may correspond to the capacitor structure 300 of FIGS. 2 to 6.

In concluding the detailed description, those skilled in the art will appreciate that many variations and modifications may be made to the embodiments without substantially departing from the principles of the present inventive concept. Therefore, the disclosed embodiments of the disclosure are used in a generic and descriptive sense only and not for purposes of limitation.

What is claimed is:

1. A semiconductor memory device comprising:
a storage pad on a substrate;
a lower electrode structure on the storage pad;
an upper support pattern on the lower electrode structure opposite the storage pad;
a capacitor dielectric film on the lower electrode structure and the upper support pattern; and
an upper electrode on the capacitor dielectric film,
wherein the lower electrode structure comprises a first lower electrode, a second lower electrode, and a third lower electrode,
wherein the second lower electrode is between the first lower electrode and the third lower electrode, and
wherein the third lower electrode extends on an upper face of the first lower electrode and an upper face of the second lower electrode that are opposite the storage pad.

2. The semiconductor memory device of claim 1,
wherein an upper face of the third lower electrode, which is opposite the storage pad, includes a convex portion.

3. The semiconductor memory device of claim 1,
wherein a lower face of the third lower electrode, which is adjacent the storage pad, is in direct contact with an upper face of the storage pad.

4. The semiconductor memory device of claim 1,
wherein a lower face of the third lower electrode, which is adjacent the storage pad, is in direct contact with the second lower electrode.

5. The semiconductor memory device of claim 1,
wherein the first lower electrode is between the storage pad and a lower face of the third lower electrode, which is adjacent the storage pad.

6. The semiconductor memory device of claim 1,
wherein an upper face of the third lower electrode and an upper face of the upper support pattern, which are opposite the storage pad, are coplanar.

7. The semiconductor memory device of claim 1,
wherein the first lower electrode includes titanium (Ti).

8. The semiconductor memory device of claim 7,
wherein the second lower electrode includes niobium (Nb).

9. The semiconductor memory device of claim 8,
wherein the third lower electrode includes titanium silicon nitride (TiSiN).

10. A semiconductor memory device comprising:
a storage pad on a substrate;
a lower electrode structure on the storage pad;
an upper support pattern on the lower electrode structure opposite the storage pad;
a capacitor dielectric film on the lower electrode structure and the upper support pattern; and
an upper electrode on the capacitor dielectric film,
wherein the lower electrode structure comprises a first lower electrode, a second lower electrode, and a third lower electrode,
wherein the first lower electrode has an outer wall that is in contact with the capacitor dielectric film, and an inner wall that is opposite the outer wall,
wherein the second lower electrode conformally extends along the inner wall of the first lower electrode, and
wherein the third lower electrode extends on an upper face of the first lower electrode and an upper face of the second lower electrode that are opposite the storage pad.

11. The semiconductor memory device of claim 10,
wherein an upper face of the third lower electrode and an upper face of the upper support pattern, which are opposite the storage pad, are coplanar.

12. The semiconductor memory device of claim 10,
wherein the upper face of the third lower electrode is farther from the storage pad than a lower face of the upper support pattern.

13. The semiconductor memory device of claim 10,
wherein a lower face of the third lower electrode, which is adjacent the storage pad, is in direct contact with the first lower electrode.

14. The semiconductor memory device of claim 10,
wherein a lower face of the third lower electrode, which is adjacent the storage pad, is in direct contact with the second lower electrode.

15. The semiconductor memory device of claim 10,
wherein the first lower electrode includes titanium (Ti).

16. The semiconductor memory device of claim 15,
wherein the second lower electrode includes niobium (Nb).

17. The semiconductor memory device of claim 16,
wherein the third lower electrode includes titanium silicon nitride (TiSiN).

18. A semiconductor memory device comprising:
a substrate comprising an active region between portions of an element isolation film and extending in a first direction, the active region comprising a first portion, and a second portion on opposing sides of the first portion;
a word line extending in a second direction different from the first direction in the substrate and the element isolation film, and crossing between the first portion of the active region and the second portion of the active region;
a bit line contact connected to the first portion of the active region;
a bit line on and connected to the bit line contact, and extending in a third direction that is different from the first and second directions;
a storage pad connected to the second portion of the active region;
a lower electrode structure on the storage pad;
an upper support pattern on the lower electrode structure opposite the storage pad;
a capacitor dielectric film on the lower electrode structure and the upper support pattern; and
an upper electrode on the capacitor dielectric film,
wherein the lower electrode structure comprises a first lower electrode, a second lower electrode, and a third lower electrode,
wherein the second lower electrode is between the first lower electrode and the third lower electrode, and
wherein the third lower electrode extends on an upper face of the first lower electrode and an upper face of the second lower electrode that are opposite the storage pad.

19. The semiconductor memory device of claim 18,
wherein an upper face of the third lower electrode and an upper face of the upper support pattern, which are opposite the storage pad, are coplanar.

20. The semiconductor memory device of claim 18,
wherein the third lower electrode comprises titanium silicon nitride (TiSiN).
